(19) United States
(12) Patent Application Publication
(10) Pub. No.: US 2016/0343791 A1
(43) Pub. Date: Nov. 24, 2016

(54) DOUBLE SIDE OLED DISPLAY DEVICE AND MANUFACTURE METHOD THEREOF

(71) Applicant: SHENZHEN CHINA STAR OPTOELECTRONICS TECHNOLOGY CO., LTD., Shenzhen, Guangdong (CN)

(72) Inventors: Yawei LIU, Shenzhen, Guangdong (CN); Yifan WANG, Shenzhen, Guangdong (CN)

(73) Assignee: Shenzhen China Star Optoelectronics Technology Co., Ltd., Shenzhen, Guangdong (CN)

(21) Appl. No.: 14/424,428

(22) PCT Filed: Feb. 9, 2015
(86) PCT No.: PCT/CN2015/072556

§ 371 Date: Feb. 26, 2015

(30) Foreign Application Priority Data
Dec. 24, 2014 (CN) 201410817962.6

(51) Int. Cl. H01L 27/32; H01L 51/00; H01L 51/52

(52) U.S. Cl. CPC H01L 27/3267; H01L 51/5246; H01L 51/524; H01L 51/0024; H01L 2251/5323; H01L 2251/533; H01L 2251/301; H01L 2227/323

(57) ABSTRACT

The present invention provides a double side OLED display device and a manufacture method thereof. The double side OLED display device comprises a first, a second substrates (11, 21) oppositely located, a first OLED display element (12) located at a side of the first substrate (11) facing the second substrate (21), a second OLED display element (22) located at a side of the second substrate (21) facing the first substrate (11) and a face seal thin film (30), being located between the first, the second substrates (11, 21) and completely covering the first, the second OLED display elements (12, 22); both the first, the second OLED display elements (12, 22) are bottom emitting light type OLED display elements, and the two are oppositely located, and respectively emit light toward the first, the second substrates (11, 21); the face seal thin film (30) bonds the first, the second substrates (11, 21) together, and packages the first, the second OLED display elements (12, 22). The structure of the double side OLED display device is simple, flimsy and easy for manufacture, and the manufacture cost is low.

### FIELD OF THE INVENTION

The present invention relates to a display technology field, and more particularly to a double side OLED display device and a manufacture method thereof.

### BACKGROUND OF THE INVENTION

The flat panel display elements possess many merits of thin frame, power saving, no radiation, etc. and have been widely used. The present flat panel displays at present mainly comprise the Liquid Crystal Display (LCD) and the Organic Light Emitting Display (OLED).

The OLED possesses many outstanding properties of self-illumination, no requirement of backlight, high contrast, ultra-thin, wide view angle, fast response speed, applicability of flexible panel, wide range of working temperature, simpler structure and process. It has become the main selection of the next generation display and has been favored by respective big display makers.

The OLED display device generally comprises a substrate, an anode located on the substrate, a Hole Injection Layer located on the anode, a Hole Transporting Layer located on the Hole Injection Layer, an emitting layer located on the Hole Transporting Layer, an Electron Transport Layer located on the emitting layer, an Electron Injection Layer located on the Electron Transport Layer and a Cathode located on the Electron Injection Layer. The principle of the illumination is that the illumination generates due to the carrier injection and recombination under the electric field driving of the semiconductor material and the organic semiconductor illuminating material. Specifically, the ITO electrode and the metal electrode are respectively employed as the anode and the cathode. Under certain voltage driving, the Electron and the Hole are respectively injected into the Electron Injection Layer and Hole Electron Injection Layer from the cathode and the anode. The Electron and the Hole respectively migrate from the Electron Transporting Layer and Hole Transporting Layer to the Emitting layer and bump into each other in the Emitting layer to form an exciton to excite the emitting molecule. The latter can illuminate after the radiative relaxation.

With the development of the display technology, the consumers do not merely ask for the display devices to possess the properties of fast response, high resolution, fine image quality but also chase the breakthrough of the functions and the display modes. Consequently, the double side OLED display device is born at the right moment. Except having various properties of the ordinary OLED display devices, the double side OLED display device also can extend the space of the images, rapidly switch and process multiple display images, which can have unimaginable application field for the advertising campaign and the portable electronic products. Most of the present double side OLED display devices are just to assemble the two independent OLED display elements back to back to realize the double side display. The structure is heavier, and the process is relatively complicated, and the manufacture cost is higher. It cannot conform to the flimsy and high CP demands what the consumers expect.

### SUMMARY OF THE INVENTION

An objective of the present invention is to provide a double side OLED display device, of which the double side lighting, display functions without influence with each other can be realized, and meanwhile, the merit that the structure of the double side OLED display device is simple, flimsy and easy for manufacture without increasing the manufacture cost is earned.

Another objective of the present invention is to provide a manufacture method of a double side OLED display device, of which the process of the method is simple, and the manufacture cost is low with high efficiency, and the structure of the double side OLED display device manufactured by the method is simple, flimsy and the double side lighting, display functions without influence with each other can be realized.

For realizing the aforesaid objectives, the present invention first provides a double side OLED display device, comprising a first substrate, a second substrate oppositely located with the first substrate, a first OLED display element located at a side of the first substrate facing the second substrate, a second OLED display element located at a side of the second substrate facing the first substrate and a face seal thin film, being located between the first substrate and the second substrate and completely covering the first, the second OLED display elements;

wherein both the first, the second OLED display elements are bottom emitting light type OLED display elements, and the two are oppositely located, and respectively emit light toward the first, the second substrates;

the face seal thin film bonds the first, the second substrates together, and packages the first, the second OLED display elements.

The first OLED display element comprises a transparent anode located at the side of the first substrate facing the second substrate, a reflective cathode and an organic emitting light layer located between the transparent anode and the reflective cathode; the second OLED display element comprises a transparent anode located at the side of the second substrate facing the first substrate, a reflective cathode and an organic emitting light layer located between the transparent anode and the reflective cathode.

The first substrate is a TFT substrate, and the second substrate is a TFT substrate.

The double side OLED display device further comprises a first inorganic package frame, located at periphery of the face seal thin film and at the side of the first substrate facing the second substrate, a second inorganic package frame, located at the periphery of the face seal thin film and at the side of the second substrate facing the first substrate and sealant located between the first, the second inorganic package frames.

Material of the first, the second inorganic package frames is Silicon Nitride.

The present invention further provides a manufacture method of a double side OLED display device, comprising steps of:

step 1, providing a first substrate, and manufacturing a first OLED display element on a side of the first substrate;

the first OLED display element is a bottom emitting light type OLED display element emitting light toward the first substrate;

step 2, providing a second substrate, and manufacturing a second OLED display element on a side of the second substrate;

the second OLED display element is a bottom emitting light type OLED display element emitting light toward the second substrate;

step 3, sticking a face seal thin film on the first substrate to make the face seal thin film completely cover the first OLED display element;

step 4, oppositely assembling and laminating the first substrate and the second substrate to oppositely locate the first, the second OLED display elements to make the face seal thin film completely cover the second OLED display element, and packaging the first, the second OLED display elements by bonding the first, the second substrates together.

The step 1 comprises: sequentially manufacturing a transparent anode, an organic emitting light layer and a reflective cathode on the side of the first substrate; the step 2 comprises: sequentially manufacturing a transparent anode, an organic emitting light layer and a reflective cathode on the side of the second substrate.

Both the first substrate in the step 1 and the second substrate in the step 2 are TFT substrates.

The step 3 further comprises: manufacturing a first inorganic package frame at periphery of the face seal thin film and at the side of the first substrate, where the first OLED display element is located, and manufacturing a second inorganic package frame corresponding to the first inorganic package frame and at the side of the second substrate where the second OLED display element is located and coating sealant on the first or the second inorganic package frame.

The step 4 further comprises: curing the sealant, and bonding the first, the second inorganic package frames together with the sealant.

Material of the first, the second inorganic package frames is Silicon Nitride.

The present invention further provides a double side OLED display device, comprising a first substrate, a second substrate oppositely located with the first substrate, a first OLED display element located at a side of the first substrate facing the second substrate, a second OLED display element located at a side of the second substrate facing the first substrate and a face seal thin film, being located between the first substrate and the second substrate and completely covering the first, the second OLED display elements;

wherein both the first, the second OLED display elements are bottom emitting light type OLED display elements, and the two are oppositely located, and respectively emit light toward the first, the second substrates;

the face seal thin film bonds the first, the second substrates together, and packages the first, the second OLED display elements;

wherein the first OLED display element comprises a transparent anode located at the side of the first substrate facing the second substrate, a reflective cathode and an organic emitting light layer located between the transparent anode and the reflective cathode; the second OLED display element comprises a transparent anode located at the side of the second substrate facing the first substrate, a reflective cathode and an organic emitting light layer located between the transparent anode and the reflective cathode;

wherein the first substrate is a TFT substrate, and the second substrate is a TFT substrate;

wherein the double side OLED display device further comprises a first inorganic package frame, located at periphery of the face seal thin film and at the side of the first substrate facing the second substrate, a second inorganic package frame, located at the periphery of the face seal thin film and at the side of the second substrate facing the first substrate and sealant located between the first, the second inorganic package frames.

The benefits of the present invention are: the present invention provides a double side OLED display device. By respectively locating the first, the second OLED display elements on the first, the second substrates which are opposite, to make the two respectively emit light toward the first, the second substrates, and by locating the face seal thin film to bond the first, the second substrates together and to package the first, the second OLED display elements, the double side lighting, display functions without influence with each other can be realized, and meanwhile, the merit that the structure of the double side OLED display device is simple, flimsy and easy for manufacture without increasing the manufacture cost is earned. The present invention provides a manufacture method of a double side OLED display device. By respectively manufacturing the first, the second OLED display elements on the first, the second substrates which are opposite, to make the two respectively emit light toward the first, the second substrates, and by sticking the face seal thin film to bond the first, the second substrates together and to package the first, the second OLED display elements, the process of the method is simple, and the manufacture cost is low with high efficiency, and the structure of the double side OLED display device manufactured by the method is simple, flimsy and the double side lighting, display functions without influence with each other can be realized.

In order to better understand the characteristics and technical aspect of the invention, please refer to the following detailed description of the present invention is concerned with the diagrams, however, provide reference to the accompanying drawings and description only and is not intended to be limiting of the invention.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a sectional structure diagram of a double side OLED display device according to the present invention;

FIG. 2 is a flowchart of a manufacture method of double side OLED display device according to the present invention.

### DETAILED DESCRIPTION OF PREFERRED EMBODIMENTS

For better explaining the technical solution and the effect of the present invention, the present invention will be further described in detail with the accompanying drawings and the specific embodiments.

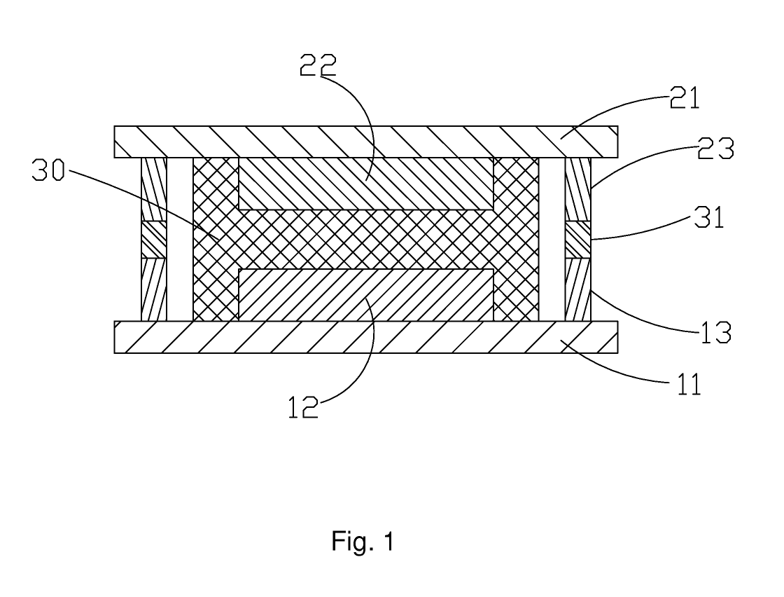

Please refer to FIG. 1. The present invention first provides a double side OLED display device, comprising a first substrate 11, a second substrate 21 oppositely located with the first substrate 11, a first OLED display element 12 located at a side of the first substrate 11 facing the second substrate 21, a second OLED display element 22 located at a side of the second substrate 21 facing the first substrate 11 and a face seal thin film 30, being located between the first, the second substrates 11, 21 and completely covering the first, the second OLED display elements 12, 22. Both the first, the second OLED display elements 12, 22 are bottom emitting light type OLED display elements, and the two are oppositely located, and respectively emit light toward the first, the second substrates 11, 21. The light emitted from the first OLED display elements 12 passes through the first substrates 11 and performs image display independently, and the light emitted from the second OLED display elements 22 passes through the second substrates 21 and performs image display independently. Thus, the first, the second OLED display elements 12, 22 can work independently from each other and show different images to realize the double side lighting, display functions without influence with each other.

The face seal thin film 30 is similar as the double-sided tape, and both sides are adhesive. Moreover, the face seal thin film 30 possesses functions of drying and blocking the water vapor and oxygen. The face seal thin film 30 bonds the first, the second substrates 11, 21 together, and packages the first, the second OLED display elements 12, 22. Compared with the bonding and packaging the substrates by locating sealant around the two substrates in a regular way, the face seal thin film 30 throughout maintains real contact with the first, the second substrates 11, 21 to raise the press resistance of the first, the second substrates 11, 21, which are hardly to be damaged by the external force. More importantly, with the face seal thin film 30 to bond the first, the second substrates 11, 21 together, and to package the first, the second OLED display elements 12, 22, the structure of the double side OLED display device becomes simple, flimsy and easy for manufacture, and the manufacture cost is low.

Specifically, both the first, the second substrates 11, 21 are transparent TFT substrates.

The first OLED display element 12 is a bottom emitting light type OLED display element, and further comprises a transparent anode located at the side of the first substrate 11 facing the second substrate 21, a reflective cathode and an organic emitting light layer located between the transparent anode and the reflective cathode; the second OLED display element 22 comprises a transparent anode located at the side of the second substrate 21 facing the first substrate 11, a reflective cathode and an organic emitting light layer located between the transparent anode and the reflective cathode. Significantly, two electrode wires are drew out from the same side of the OLED display element.

Besides, for promoting the package result in advance, the double side OLED display device further comprises a first inorganic package frame 13, located at periphery of the face seal thin film 30 and at the side of the first substrate 11 facing the second substrate 21, a second inorganic package frame 23, located at the periphery of the face seal thin film 30 and at the side of the second substrate 21 facing the first substrate 11 and sealant 31 located between the first, the second inorganic package frames 13, 23. Furthermore, material of the first, the second inorganic package frames 13, 23 is Silicon Nitride (SiNx). The internals of the first, the second inorganic package frames 13, 23 are compact, and the water vapor cannot penetrate, and only the sealant 31 can allow few water vapor and oxygen to pass through. Accordingly, the invasions of the water vapor and oxygen can be prevented more effectively to package and protect the first, the second OLED display elements 12, 22 better.

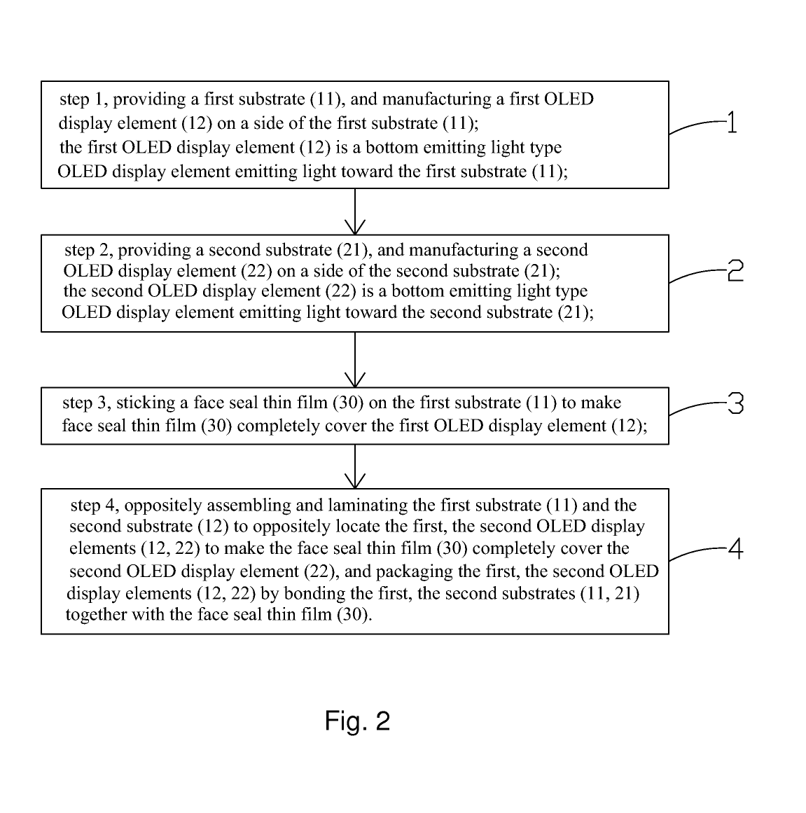

Please refer to FIG. 2 in combination of FIG. 1. The present invention further provides a manufacture method of a double side OLED display device, comprising steps of:

step 1, providing a first substrate 11, and manufacturing a first OLED display element 12 on a side of the first substrate 11.

The first substrate 11 is a transparent TFT substrate. The first OLED display element 12 is a bottom emitting light type OLED display element emitting light toward the first substrate 11.

Specifically, the step 1 comprises: sequentially manufacturing a transparent anode, an organic emitting light layer and a reflective cathode on the side of the first substrate 11 to obtain the first OLED display element 12.

step 2, providing a second substrate 21, and manufacturing a second OLED display element 22 on a side of the second substrate 21.

The second substrate 21 is a transparent TFT substrate. The second OLED display element 22 is a bottom emitting light type OLED display element emitting light toward the second substrate 21.

Specifically, the step 2 comprises: sequentially manufacturing a transparent anode, an organic emitting light layer and a reflective cathode on the side of the second substrate 22 to obtain the second OLED display element 22; two electrode wires are drew out from the same side of the OLED display element.

step 3, sticking a face seal thin film 30 on the first substrate 11 to make the face seal thin film 30 completely cover the first OLED display element 12.

The face seal thin film 30 is similar as the double-sided tape, and both sides are adhesive. Moreover, the face seal thin film 30 possesses functions of drying and blocking the water vapor and oxygen.

Furthermore, the step 3 further comprises: manufacturing a first inorganic package frame 13 at periphery of the face seal thin film 30 and at the side of the first substrate 11, where the first OLED display element 12 is located, and manufacturing a second inorganic package frame 23 corresponding to the first inorganic package frame 13 and at the side of the second substrate 21 where the second OLED display element 22 is located and coating sealant 31 on the first or the second inorganic package frame 13, 23.

Material of the first, the second inorganic package frames 13, 23 is Silicon Nitride.

step 4, oppositely assembling and laminating the first substrate 11 and the second substrate 12 to oppositely locate the first, the second OLED display elements 12, 22 to make the face seal thin film 30 completely cover the second OLED display element 22, and packaging the first, the second OLED display elements 12, 22 by bonding the first, the second substrates 11, 21 together with the face seal thin film 30.

Furthermore, the step 4 further comprises curing the sealant 31, and bonding the first, the second inorganic package frames 13, 23 together with the sealant 31.

Thus, the manufacture of the double side OLED display device is accomplished.

In the double side OLED display device manufactured by the aforesaid method, both the first, the second OLED display elements 12, 22 are bottom emitting light type OLED display elements, and the two are oppositely located, and respectively emit light toward the first, the second substrates 11, 21. The light emitted from the first OLED display elements 12 passes through the first substrates 11 and performs image display independently, and the light emitted from the second OLED display elements 22 passes through the second substrates 21 and performs image display independently. Thus, the first, the second OLED display elements 12, 22 can work independently from each other and show different images to realize the double side lighting, display functions without influence with each other. With the face seal thin film 30 to bond the first, the second substrates 11, 21 together, and to package the first, the second OLED display elements 12, 22 to raise the press resistance of the first, the second substrates 11, 21, which are hardly to be damaged by the external force, the structure of the double side OLED display device becomes simple, flimsy and easy for manufacture, and the manufacture cost is low in advance. The internals of the first, the second inorganic package frames 13, 23 are compact, and the water vapor cannot penetrate, and only the sealant 31 can allow few water vapor and oxygen to pass through. Accordingly, the invasions of the water vapor and oxygen can be prevented more effectively to package and protect the first, the second OLED display elements 12, 22 better.

In conclusion, in the double side OLED display device of the present invention, by respectively locating the first, the second OLED display elements on the first, the second substrates which are opposite, to make the two respectively emit light toward the first, the second substrates, and by locating the face seal thin film to bond the first, the second substrates together and to package the first, the second OLED display elements, the double side lighting, display functions without influence with each other can be realized, and meanwhile, the merit that the structure of the double side OLED display device is simple, flimsy and easy for manufacture without increasing the manufacture cost is earned. In the manufacture method of a double side OLED display device of the present invention, by respectively manufacturing the first, the second OLED display elements on the first, the second substrates which are opposite, to make the two respectively emit light toward the first, the second substrates, and by sticking the face seal thin film to bond the first, the second substrates together and to package the first, the second OLED display elements, the process of the method is simple, and the manufacture cost is low with high efficiency, and the structure of the double side OLED display device manufactured by the method is simple, flimsy and the double side lighting, display functions without influence with each other can be realized.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A double side OLED display device, comprising a first substrate, a second substrate oppositely located with the first substrate, a first OLED display element located at a side of the first substrate facing the second substrate, a second OLED display element located at a side of the second substrate facing the first substrate and a face seal thin film, being located between the first substrate and the second substrate and completely covering the first, the second OLED display elements;
wherein both the first, the second OLED display elements are bottom emitting light type OLED display elements, and the two are oppositely located, and respectively emit light toward the first, the second substrates;
the face seal thin film bonds the first, the second substrates together, and packages the first, the second OLED display elements.

2. The double side OLED display device according to claim 1, wherein the first OLED display element comprises a transparent anode located at the side of the first substrate facing the second substrate, a reflective cathode and an organic emitting light layer located between the transparent anode and the reflective cathode; the second OLED display element comprises a transparent anode located at the side of the second substrate facing the first substrate, a reflective cathode and an organic emitting light layer located between the transparent anode and the reflective cathode.

3. The double side OLED display device according to claim 1, wherein the first substrate is a TFT substrate, and the second substrate is a TFT substrate.

4. The double side OLED display device according to claim 1, further comprising a first inorganic package frame, located at periphery of the face seal thin film and at the side of the first substrate facing the second substrate, a second inorganic package frame, located at the periphery of the face seal thin film and at the side of the second substrate facing the first substrate and sealant located between the first, the second inorganic package frames.

5. The double side OLED display device according to claim 4, wherein material of the first, the second inorganic package frames is Silicon Nitride.

6. A manufacture method of a double side OLED display device, comprising steps of:
step 1, providing a first substrate, and manufacturing a first OLED display element on a side of the first substrate;
the first OLED display element is a bottom emitting light type OLED display element emitting light toward the first substrate;
step 2, providing a second substrate, and manufacturing a second OLED display element on a side of the second substrate;
the second OLED display element is a bottom emitting light type OLED display element emitting light toward the second substrate;
step 3, sticking a face seal thin film on the first substrate to make the face seal thin film completely cover the first OLED display element;
step 4, oppositely assembling and laminating the first substrate and the second substrate to oppositely locate the first, the second OLED display elements to make the face seal thin film completely cover the second OLED display element, and packaging the first, the second OLED display elements by bonding the first, the second substrates together.

7. The manufacture method of the double side OLED display device according to claim 6, wherein the step 1 comprises: sequentially manufacturing a transparent anode, an organic emitting light layer and a reflective cathode on the side of the first substrate; the step 2 comprises: sequentially manufacturing a transparent anode, an organic emitting light layer and a reflective cathode on the side of the second substrate.

8. The manufacture method of the double side OLED display device according to claim 6, wherein both the first substrate in the step 1 and the second substrate in the step 2 are TFT substrates.

9. The manufacture method of the double side OLED display device according to claim 6, wherein the step 3 further comprises: manufacturing a first inorganic package frame at periphery of the face seal thin film and at the side of the first substrate, where the first OLED display element is located, and manufacturing a second inorganic package frame corresponding to the first inorganic package frame and at the side of the second substrate where the second OLED display element is located and coating sealant on the first or the second inorganic package frame.

10. The manufacture method of the double side OLED display device according to claim 9, wherein the step 4 further comprises: curing the sealant, and bonding the first, the second inorganic package frames together with the sealant;
Material of the first, the second inorganic package frames is Silicon Nitride.

11. A double side OLED display device, comprising a first substrate, a second substrate oppositely located with the first substrate, a first OLED display element located at a side of the first substrate facing the second substrate, a second OLED display element located at a side of the second substrate facing the first substrate and a face seal thin film, being located between the first substrate and the second substrate and completely covering the first, the second OLED display elements;
wherein both the first, the second OLED display elements are bottom emitting light type OLED display elements, and the two are oppositely located, and respectively emit light toward the first, the second substrates;
the face seal thin film bonds the first, the second substrates together, and packages the first, the second OLED display elements;
wherein the first OLED display element comprises a transparent anode located at the side of the first substrate facing the second substrate, a reflective cathode and an organic emitting light layer located between the transparent anode and the reflective cathode; the second OLED display element comprises a transparent anode located at the side of the second substrate facing the first substrate, a reflective cathode and an organic emitting light layer located between the transparent anode and the reflective cathode;
wherein the first substrate is a TFT substrate, and the second substrate is a TFT substrate;
wherein the double side OLED display device further comprises a first inorganic package frame, located at periphery of the face seal thin film and at the side of the first substrate facing the second substrate, a second inorganic package frame, located at the periphery of the face seal thin film and at the side of the second substrate facing the first substrate and sealant located between the first, the second inorganic package frames.

12. The double side OLED display device according to claim 11, wherein material of the first, the second inorganic package frames is Silicon Nitride.
